(19) United States
(12) Patent Application Publication
(10) Pub. No.: US 2018/0190622 A1
(43) Pub. Date: Jul. 5, 2018

(54) 3-D STACKING SEMICONDUCTOR ASSEMBLY HAVING HEAT DISSIPATION CHARACTERISTICS

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/908,838

(22) Filed: Mar. 1, 2018

Related U.S. Application Data
(63) Continuation-in-part of application No. 15/415,844, filed on Jan. 25, 2017.
Application No. 15/415,844 is a continuation-in-part of application No. 15/415,846, filed on Jan. 25, 2017.
Application No. 15/415,846 is a continuation-in-part of application No. 15/473,629, filed on Mar. 30, 2017.
Application No. 15/473,629 is a continuation-in-part of application No. 15/642,253, filed on Jul. 5, 2017.
Application No. 15/415,844 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/415,846 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/473,629 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/353,537 is a continuation-in-part of application No. 15/415,844, filed on Jan. 25, 2017.
Application No. 15/415,844 is a continuation-in-part of application No. 15/415,846, filed on Jan. 25, 2017.
Application No. 15/415,846 is a continuation-in-part of application No. 15/462,536, filed on Mar. 17, 2017.
Application No. 15/642,253 is a continuation-in-part of application No. 14/621,332, filed on Feb. 12, 2015.
Application No. 14/621,332 is a continuation-in-part of application No. 14/846,987, filed on Sep. 7, 2015.
Application No. 15/289,126 is a continuation-in-part of application No. 15/166,185, filed on May 26, 2016.
Application No. 15/353,537 is a continuation-in-part of application No. 15/166,185, filed on May 26, 2016.
Application No. 15/166,185 is a continuation-in-part of application No. 15/289,126, filed on Oct. 8, 2016.
Application No. 15/462,536 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 14/846,987 is a continuation-in-part of application No. 14/621,332, filed on Feb. 12, 2015.
(60) Provisional application No. 62/166,771, filed on May 27, 2015.
(60) Provisional application No. 61/949,652, filed on Mar. 7, 2014.

(51) Int. Cl. H01L 25/065; H01L 23/495; H01L 23/498; H01L 23/538; H01L 23/18

(52) U.S. Cl. CPC H01L 25/0657; H01L 23/49527; H01L 23/49575; H01L 23/4952; H01L 24/16; H01L 23/49568; H01L 23/5384; H01L 23/18; H01L 2225/06517; H01L 23/49805

(57) ABSTRACT

A semiconductor assembly having heat dissipation characteristics includes stacked semiconductor chips thermally conductible to a thermal pad of an interconnect substrate and electrically connected to the interconnect substrate through bonding wire. The bonding wires extending from a primary routing circuitry in between the stacked chips can accommodate the height difference between the stacked chips and the interconnect substrate. These wires can also effectively compensate for the thermal expansion mismatch between the stacked chips and the interconnect substrate, thereby allowing a higher manufacturing yield and better reliability.

### CROSS REFERENCE TO RELATED APPLICATIONS

This application is a continuation-in-part of U.S. application Ser. No. 15/415,844 filed Jan. 25, 2017, a continuation-in-part of U.S. application Ser. No. 15/415,846 filed Jan. 25, 2017, a continuation-in-part of U.S. application Ser. No. 15/473,629 filed Mar. 30, 2017 and a continuation-in-part of U.S. application Ser. No. 15/642,253 filed Jul. 5, 2017. The U.S. application Ser. Nos. 15/415,844, and 15/415,846 are continuation-in-part of U.S. application Ser. No. 15/166,185 filed May 26, 2016, continuation-in-part of U.S. application Ser. No. 15/289,126 filed Oct. 8, 2016 and continuation-in-part of U.S. application Ser. No. 15/353,537 filed Nov. 16, 2016. The U.S. application Ser. No. 15/473,629 is a continuation-in-part of U.S. application Ser. No. 15/166,185 filed May 26, 2016, a continuation-in-part of U.S. application Ser. No. 15/289,126 filed Oct. 8, 2016, a continuation-in-part of U.S. application Ser. No. 15/353,537 filed Nov. 16, 2016, a continuation-in-part of U.S. application Ser. No. 15/415,844 filed Jan. 25, 2017, a continuation-in-part of U.S. application Ser. No. 15/415,846 filed Jan. 25, 2017 and a continuation-in-part of U.S. application Ser. No. 15/462,536 filed Mar. 17, 2017. The U.S. application Ser. No. 15/642,253 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The U.S. application Ser. Nos. 15/462,536 is a continuation-in-part of U.S. application Ser. No. 15/166,185 filed May 26, 2016, a continuation-in-part of U.S. Application Ser. No. 15/289,126 filed Oct. 8, 2016 and a continuation-in-part of U.S. application Ser. No. 15/353,537 filed Nov. 16, 2016. The U.S. application Ser. No. 14/846,987 is a continuation-in-part of U.S. application Ser. No. 14/621,332 filed Feb. 12, 2015. The U.S. application Ser. No. 14/621,332 claims the benefit of filing date of U.S. Provisional Application Ser. No. 61/949,652 filed Mar. 7, 2014. The entirety of each of said Applications is incorporated herein by reference.

### FIELD OF THE INVENTION

The present invention relates to a semiconductor assembly and, more particularly, to a semiconductor assembly in which a stacked semiconductor subassembly is thermally conductible to a thermal pad of an interconnect substrate and electrically connected to the interconnect substrate through bonding wires.

### DESCRIPTION OF RELATED ART

Market trends of multimedia devices demand for faster and slimmer designs. One of assembly approaches is to interconnect two devices with stacking configuration so that the routing distance between the two devices can be the shortest possible. As the stacked devices can talk directly to each other with reduced latency, the assembly's signal integrity and additional power saving capability are greatly improved. However, as semiconductor devices are susceptible to performance degradation at high operational temperatures, stacking chips without proper heat dissipation would worsen devices' performance, decrease reliability and reduce the useful lifetime of the assembly.

U.S. Pat. Nos. 5,790,384, 6,984,544, 7,026,719, 8,971,053, and 9,263,332 disclose various face-to-face 3D stacking assemblies for such purposes. However, as there is no heat dissipation channel associated with these stacked chips, heat generated by the closely stacked chips can be accumulated quickly and results in immediate failure during operation. Further, as these face-to-face subassemblies require soldering material to connect to the external environment, solder cracking or dislocation between the subassembly and the interconnect substrate due to warpage or thermal expansion mismatch may lead to serious reliability concerns.

For the reasons stated above, and for other reasons stated below, an urgent need exists to provide a semiconductor assembly that can address high packaging density, better signal integrity and high thermal dissipation requirements.

### SUMMARY OF THE INVENTION

An objective of the present invention is to provide a semiconductor assembly in which a stacked semiconductor subassembly is mounted to a thermal pad of an interconnect substrate. As the heat generated by the stacked chips can be dissipated effectively, thermal characteristics of the assembly can be greatly improved.

The semiconductor assembly may further include a plurality of bonding wires extending from a primary routing circuitry in between the stacked chips to the interconnect substrate so that the stacked subassembly can be electrically connected to the external environment. The bonding wires can accommodate the height difference between the primary routing circuitry and the interconnect substrate, and can effectively compensate for the thermal expansion mismatch between the subassembly and the interconnect substrate, thereby allowing a higher manufacturing yield and better reliability.

In accordance with the foregoing and other objectives, the present invention provides a three-dimensional semiconductor assembly having heat dissipation characteristics, comprising: a stacked semiconductor subassembly that includes a primary routing circuitry, a first device and a second device, wherein (i) the primary routing circuitry has a first surface in a first direction, a second surface in an opposite second direction, first conductive pads at the first surface, and second conductive pads at the second surface electrically connected to the first conductive pads, (ii) the first device is disposed over the first surface of the primary routing circuitry and electrically coupled to the primary routing circuitry through the first conductive pads, and (iii) the second device is disposed over the second surface of the primary routing circuitry and electrically coupled to the primary routing circuitry through the second conductive pads; an interconnect substrate having a thermal pad and a plurality of metal leads disposed about the periphery of the thermal pad, wherein the thermal pad and the metal leads each have a front side facing in the first direction and the front side of the thermal pad is attached to the second device by a thermal conducting material; and a plurality of bonding wires that electrically connect the first surface of the primary routing circuitry to the front sides of the metal leads.

In another aspect, the present invention provides a method of making another three-dimensional semiconductor assembly having heat dissipation characteristics, comprising: a stacked semiconductor subassembly that includes a primary routing circuitry, a first device and a second device, wherein (i) the primary routing circuitry has a first surface in a first direction, a second surface in an opposite second direction, first conductive pads at the first surface, and second conductive pads at the second surface electrically connected to the first conductive pads, (ii) the first device is disposed over the first surface of the primary routing circuitry and electrically coupled to the primary routing circuitry through the first conductive pads, and (iii) the second device is disposed over the second surface of the primary routing circuitry and electrically coupled to the primary routing circuitry through the second conductive pads; an interconnect substrate that includes a thermal pad and a surrounding layer, wherein (i) the thermal pad has a front side facing in the first direction, and the front side of the thermal pad is attached to the second device by a thermal conducting material, (ii) the surrounding layer of the interconnect substrate has a dielectric layer and contact pads, (iii) the dielectric layer is bonded to sidewalls of the thermal pad and has a front surface facing in the first direction, and (iv) the contact pads are disposed on the front surface of the dielectric layer; a plurality of terminals that are electrically coupled to the contact pads and disposed about peripheral edges of the stacked semiconductor subassembly; and a plurality of bonding wires that are attached to the primary routing circuitry and the contact pads of the surrounding layer to electrically connect the stacked semiconductor subassembly to the terminals.

The semiconductor assembly according to the present invention have numerous advantages. For instance, stacking and electrically coupling the first and second devices to both opposite sides of the primary routing circuitry can offer the shortest interconnect distance between the first and second devices. Mounting the stacked semiconductor subassembly on the thermal pad of the interconnect substrate is particularly advantageous as the thermal pad can provide thermal dissipation for the second device. Additionally, attaching the bonding wires to the primary routing circuitry and interconnect substrate can offer a reliable vertical connecting channel for interconnecting the devices assembled in the subassembly to external environment.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1, 2 and 3 are cross-sectional, top and bottom perspective views, respectively, of a primary routing circuitry bonded with a stiffener in accordance with the first embodiment of the present invention;

FIGS. 4, 5 and 6 are cross-sectional, top and bottom perspective views, respectively, of the structure of FIGS. 1, 2 and 3 further provided with a first device and a second device in accordance with the first embodiment of the present invention;

FIGS. 7 and 8 are cross-sectional and top perspective views, respectively, of an interconnect substrate in accordance with the first embodiment of the present invention;

FIGS. 9 and 10 are cross-sectional and top perspective views, respectively, of the structure of FIGS. 7 and 8 further provided with the subassembly of FIGS. 4, 5 and 6 in accordance with the first embodiment of the present invention;

FIGS. 11 and 12 are cross-sectional and top perspective views, respectively, of the structure of FIGS. 9 and 10 further provided with bonding wires in accordance with the first embodiment of the present invention;

FIG. 13 is a cross-sectional view of the structure of FIGS. 11 and 12 further provided with a molding compound in accordance with the first embodiment of the present invention;

FIGS. 14, 15 and 16 are cross-sectional, top and bottom perspective views, respectively, of a semiconductor assembly trimmed from the structure of FIG. 13 in accordance with the first embodiment of the present invention;

FIG. 17 is a cross-sectional view of another aspect of the semiconductor assembly in accordance with the first embodiment of the present invention;

FIGS. 18 and 19 are cross-sectional and bottom perspective views, respectively, of yet another aspect of the semiconductor assembly in accordance with the first embodiment of the present invention;

FIG. 20 is a cross-sectional view of a stacked semiconductor subassembly in accordance with the second embodiment of the present invention;

FIG. 21 is a cross-sectional view of the structure of FIG. 20 further provided with an interconnect substrate in accordance with the second embodiment of the present invention;

FIG. 22 is a cross-sectional view of the structure of FIG. 21 further provided with bonding wires in accordance with the second embodiment of the present invention;

FIG. 23 is a cross-sectional view of the structure of FIG. 22 further provided with a molding compound in accordance with the second embodiment of the present invention;

FIG. 24 is a cross-sectional view of a semiconductor assembly trimmed from the structure of FIG. 23 in accordance with the second embodiment of the present invention;

FIG. 25 is a cross-sectional view of another aspect of the semiconductor assembly in accordance with the second embodiment of the present invention;

FIGS. 26 and 27 are cross-sectional and top perspective views, respectively, of a lead frame in accordance with the third embodiment of the present invention;

FIGS. 28 and 29 are cross-sectional and top perspective views, respectively, of the structure of FIGS. 26 and 27 further provided with a compound layer to finish the fabrication of an interconnect substrate in accordance with the third embodiment of the present invention;

FIGS. 30 and 31 are cross-sectional and top perspective views, respectively, of the structure of FIGS. 28 and 29 further provided with the subassembly of FIGS. 4, 5 and 6 and bonding wires in accordance with the third embodiment of the present invention;

FIGS. 32 and 33 are cross-sectional and top perspective views, respectively, of a semiconductor assembly trimmed from the structure of FIGS. 30 and 31 and further provided with a molding compound in accordance with the third embodiment of the present invention;

FIGS. 34 and 35 are cross-sectional and top perspective views, respectively, of another aspect of the semiconductor assembly in accordance with the third embodiment of the present invention;

FIGS. 36 and 37 are cross-sectional and top perspective views, respectively, of yet another aspect of the semiconductor assembly in accordance with the third embodiment of the present invention;

FIG. 38 is a cross-sectional view of a lead frame in accordance with the fourth embodiment of the present invention;

FIG. 39 is a cross-sectional view of the structure of FIG. 38 further provided with a compound layer in accordance with the fourth embodiment of the present invention;

FIG. 40 is a cross-sectional view of the structure of FIG. 39 further provided with an external routing circuitry to finish the fabrication of an interconnect substrate in accordance with the fourth embodiment of the present invention;

FIG. 41 is a cross-sectional view of the structure of FIG. 40 further provided with the subassembly of FIG. 4 and bonding wires in accordance with the fourth embodiment of the present invention;

FIG. 42 is a cross-sectional view of a semiconductor assembly trimmed from the structure of FIG. 41 and further provided with a molding compound in accordance with the fourth embodiment of the present invention;

FIG. 43 is a cross-sectional view of another aspect of the semiconductor assembly in accordance with the fourth embodiment of the present invention;

FIG. 44 is a cross-sectional view of a semiconductor assembly in accordance with the fifth embodiment of the present invention;

FIG. 45 is a cross-sectional view of another aspect of the semiconductor assembly in accordance with the fifth embodiment of the present invention;

FIG. 46 is a cross-sectional view of a semiconductor assembly in accordance with the sixth embodiment of the present invention; and

FIG. 47 is a cross-sectional view of another aspect of the semiconductor assembly in accordance with the sixth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

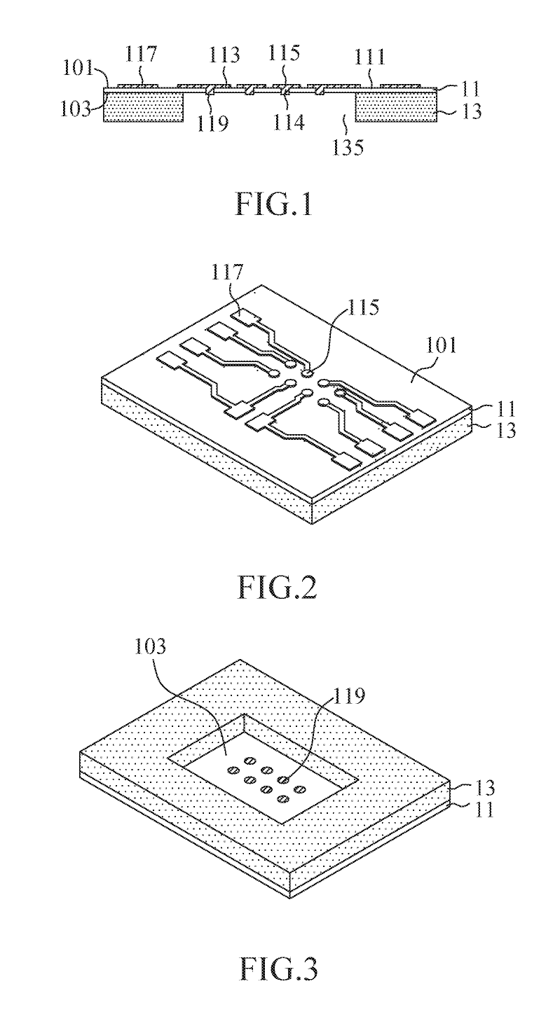

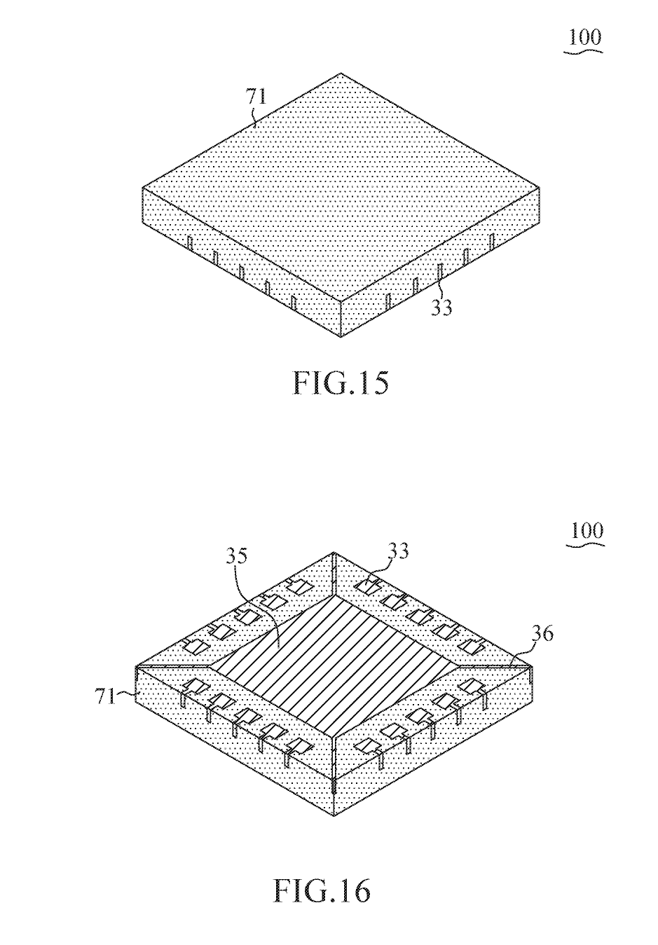

FIGS. 1-16 are schematic views showing a method of making a semiconductor assembly that includes a primary routing circuitry, a stiffener, a first device, a second device, an interconnect substrate, bonding wires and a molding compound in accordance with the first embodiment of the present invention.

FIGS. 1, 2 and 3 are cross-sectional, top and bottom perspective views, respectively, of a primary routing circuitry 11 bonded with a stiffener 13. In this embodiment, the primary routing circuitry 11 is a multi-layered buildup circuitry and includes a dielectric layer 111 and a wiring layer 113. The dielectric layer 111 typically has a thickness of 50 microns, and can be made of epoxy resin, glass-epoxy, polyimide, or the like. The wiring layer 113 typically is made of copper and extends laterally on the dielectric layer 111 and includes conductive vias 114 extending through the dielectric layer 111. As shown in FIGS. 2 and 3, the wiring layer 113 provides first conductive pads 115 and terminal pads 117 at the first surface 101 and second conductive pads 119 at the second surface 103. The terminal pads 117 have larger pad size and pitch than those of first conductive pads 115, and the second conductive pads 119 are exposed by an aperture 135 of the stiffener 13 on the second surface 103 of the primary routing circuitry 11. The stiffener 13 may be made of resin, ceramic, metal, composites of metal, or a single or multi-layer circuitry structure which has enough mechanical robustness, and provides mechanical support for the substrate.

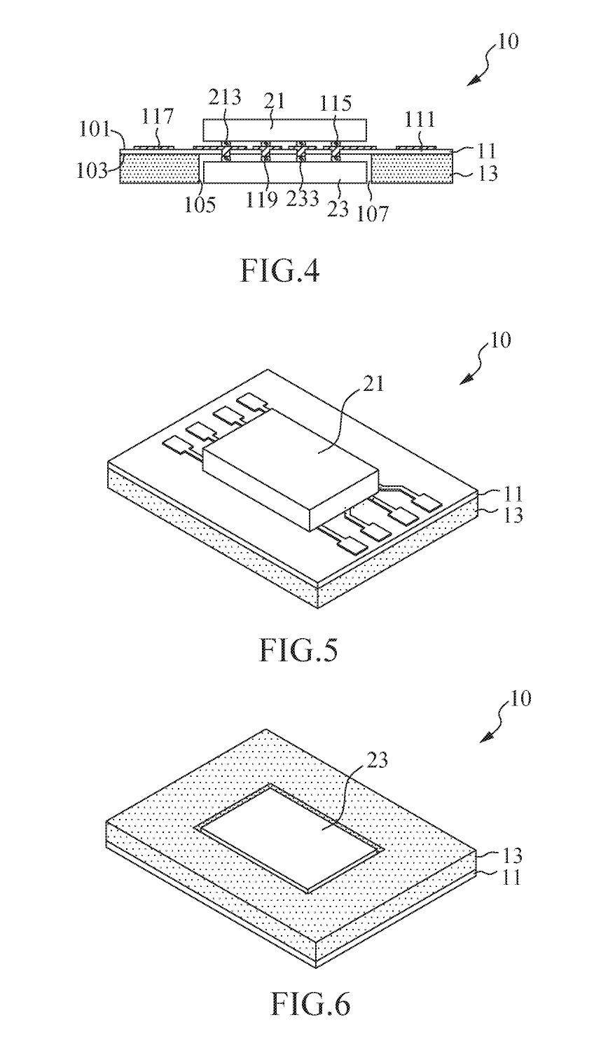

FIGS. 4, 5 and 6 are cross-sectional, top and bottom perspective views, respectively, of the structure with a first device 21 and a second device 23 electrically coupled to the primary routing circuitry 11. At this stage, a stacked semiconductor subassembly 10 is accomplished and includes the primary routing circuitry 11, the stiffener 13, the first device 21, and the second device 23. The first device 21 is disposed over the first surface 101 of the primary routing circuitry 11, whereas the second device 23 is disposed in a cavity 107 formed by the second surface 103 of the primary routing circuitry 11 and the interior sidewalls 105 of the aperture 135 of the stiffener 13. In this embodiment, the first device 21 and the second device 23 are illustrated as bare chips and electrically coupled to the primary routing circuitry 11 by first conductive bumps 213 and second conductive bumps 233, respectively. The first device 21 is electrically coupled to the wiring layer 113 of the primary routing circuitry 11 by the first conductive bumps 213 in contact with the first device 21 and the first conductive pads 115. The second device 23 is electrically coupled to the wiring layer 113 of the primary routing circuitry 11 by the second conductive bumps 233 in contact with the second device 23 and the second conductive pads 119. As a result, the first device 21 and the second device 23 are electrically connected to each other by the primary routing circuitry 11.

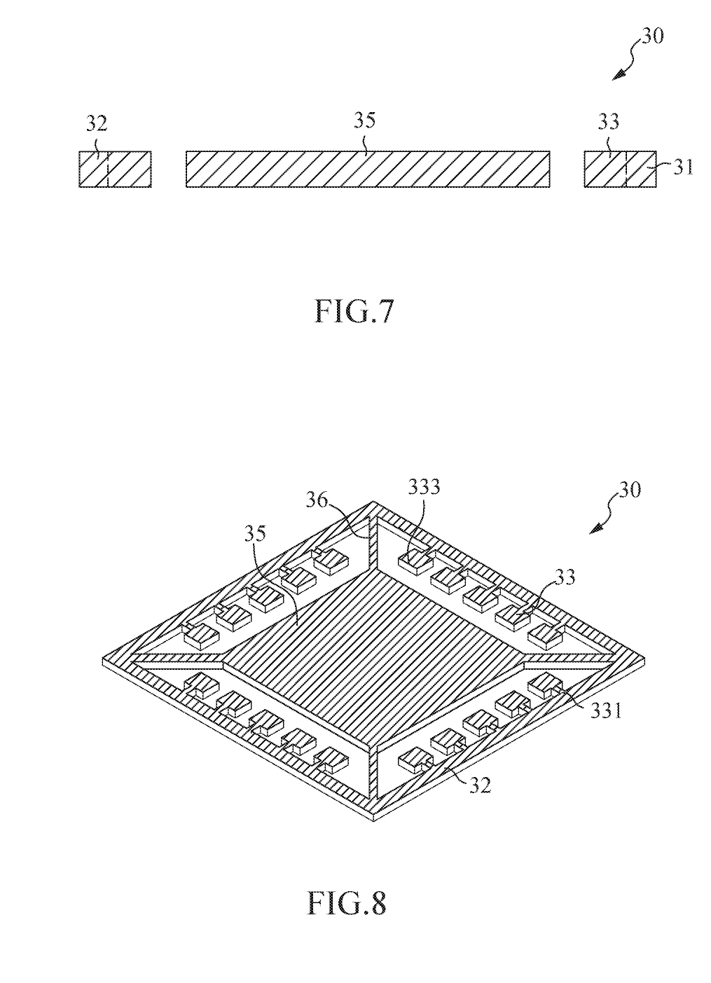

FIGS. 7 and 8 are cross-sectional and top perspective views, respectively, of an interconnect substrate 30. In this illustration, the interconnect substrate 30 is a lead frame 31 that typically is made of copper alloys, steel or alloy 42 and can be formed by a wet etching or stamping/punching process from a rolled metal strip. The etching process may be a one-sided or two-sided etching to etch through the metal strip and thereby transfer the metal strip into a desired overall pattern of the lead frame 31. In this embodiment, the lead frame 31 has a uniform thickness in a range from about 0.15 mm to about 1.0 mm, and includes a metal frame 32, a plurality of metal leads 33, a thermal pad 35 and a plurality of tie bars 36. The metal leads 33 laterally extend from the metal frame 32 toward the central area within the metal frame 32. As a result, the metal leads 33 each have an outer end 331 integrally connected to interior sidewalls of the metal frame 32, and an inner end 333 directed inwardly away from the metal frame 32. The thermal pad 35 is a metal pad and located at the central area within the metal frame 32 and connected to the metal frame 32 by the tie bars 36.

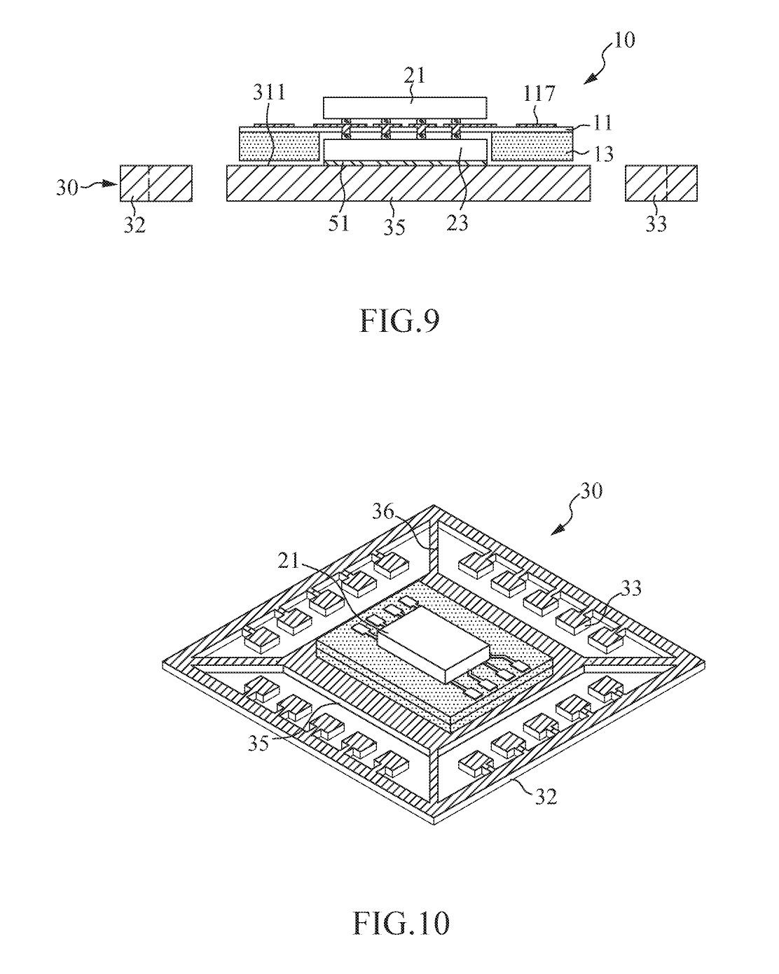

FIGS. 9 and 10 are cross-sectional and top perspective views, respectively, of the structure with the stacked semiconductor subassembly 10 of FIG. 4 attached on the interconnect substrate 30. The stacked semiconductor subassembly 10 of FIG. 4 is mounted on the thermal pad 35 of the interconnect substrate 30, with the second device 23 attached to the front side 311 of the thermal pad 35 using a thermal conducting material 51.

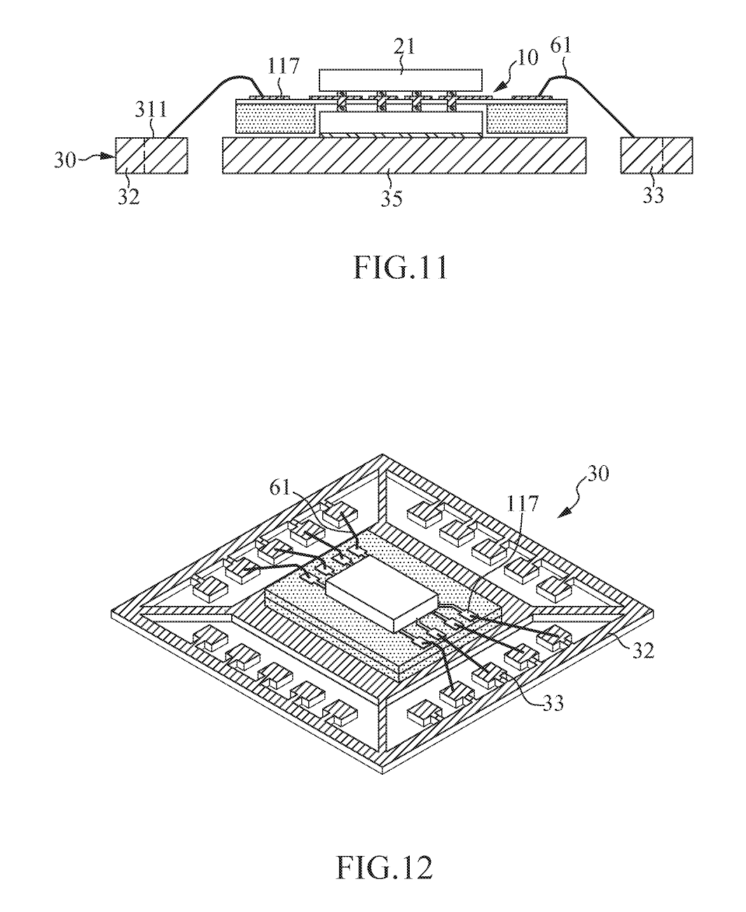

FIGS. 11 and 12 are cross-sectional and top perspective views, respectively, of the structure with bonding wires 61 attached to the stacked semiconductor subassembly 10 and the interconnect substrate 30 typically by gold or copper ball bonding, or gold or aluminum wedge bonding. The bonding wires 61 contact and are electrically coupled to the terminal pads 117 of the primary routing circuitry 11 and the front sides 311 of the metal leads 33 of the interconnect substrate 30. As a result, the first device 21 and the second device 23 are electrically connected to the interconnect substrate 30 through the primary routing circuitry 11 and the bonding wires 61.

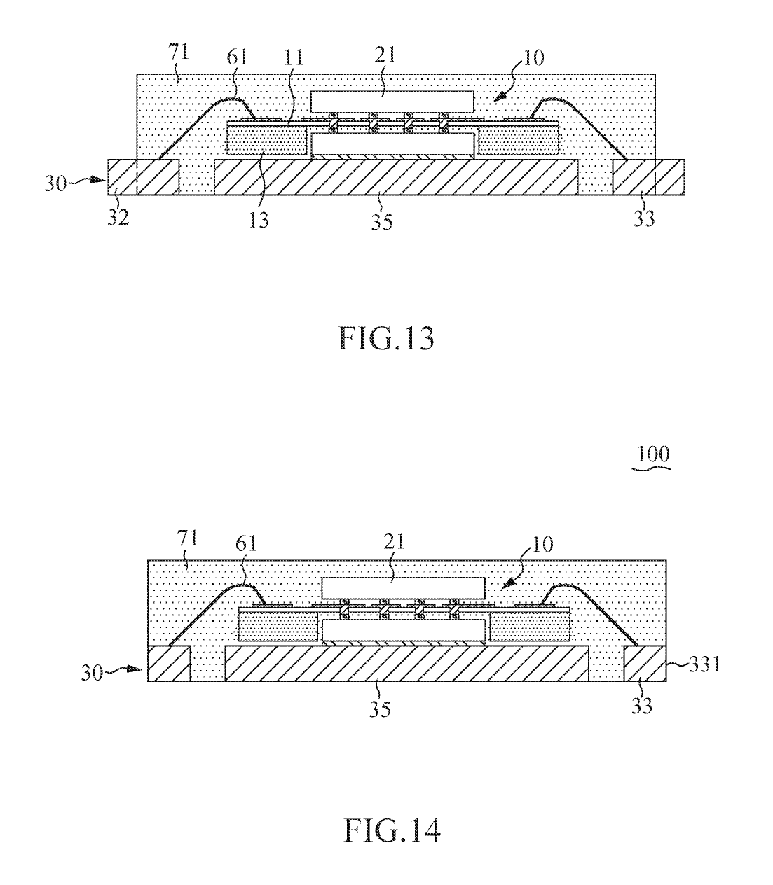

FIG. 13 is a cross-sectional view of the structure provided with a molding compound 71. The molding compound 71 covers and encapsulates the primary routing circuitry 11, the stiffener 13, the first device 21 and the bonding wires 61 from above, and further extends into spaces between the metal leads 33 and gaps between the thermal pad 35 and the metal leads 33.

FIGS. 14, 15 and 16 are cross-sectional, top and bottom perspective views, respectively, of a semiconductor assembly 100 after removal of the metal frame 32. Removal of the metal frame 32 can be done by various methods including chemical etching, mechanical trimming/cutting or sawing, and separated. As a result, the metal frame 32 is separated from the outer ends 331 of the metal leads 33. At this stage, the interconnect substrate 30 includes the metal leads 33, the thermal pad 35 and the tie bars 36, and the outer ends 331 of the metal leads 33 are situated at peripheral edges of the interconnect substrate 30 and have a lateral surface flush with peripheral edges of the molding compound 71.

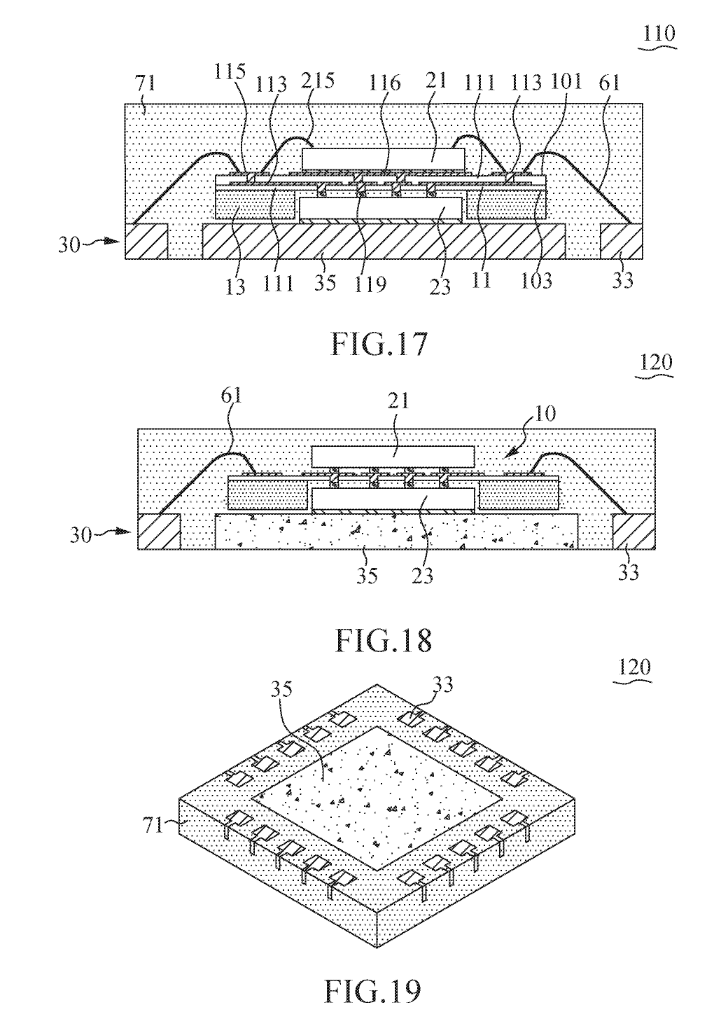

FIG. 17 is a cross-sectional view of another aspect of the semiconductor assembly according to the first embodiment of the present invention. The semiconductor assembly 110 is similar to that illustrated in FIG. 14, except that the primary routing circuitry 11 includes a plurality of dielectric layers 111 and a plurality of wiring layers 113 serially formed in an alternate fashion, and the first device 21 is electrically connected to the primary routing circuitry 11 by bonding wires 215. In this aspect, the primary routing circuitry 11 has first conductive pads 115 and a metal paddle 116 at its first surface 101 and second conductive pads 119 at its second surface 103. The first device 21 is attached on the metal paddle 116 and electrically connected to the first conductive pads 115 by the bonding wires 215. Further, the first conductive pads 115 are electrically connected to the metal leads 33 by the bonding wires 61.

FIGS. 18 and 19 are cross-sectional and bottom perspective views, respectively, of yet another aspect of the semiconductor assembly according to the first embodiment of the present invention. The semiconductor assembly 120 is similar to that illustrated in FIG. 14, except that the thermal pad 35 is a thermally conductive and electrically insulating pad and the interconnect substrate 30 includes no tie bars integral with the thermal pad 35. The thermally conductive and electrically insulating pad 35 typically is made of a material having high elastic modulus and low coefficient of thermal expansion (for example, 2×10⁻⁶ K⁻¹ to 10×10⁻⁶ K⁻¹), such as ceramic, silicon, glass or others. In this embodiment, the thermal pad 35 is a ceramic pad having a thickness substantially equal to the thickness of the metal leads 33. As a result, the thermal pad 35 not only provides primary heat conduction, but also offers a CTE-compensated platform for the second device 23.

### Embodiment 2

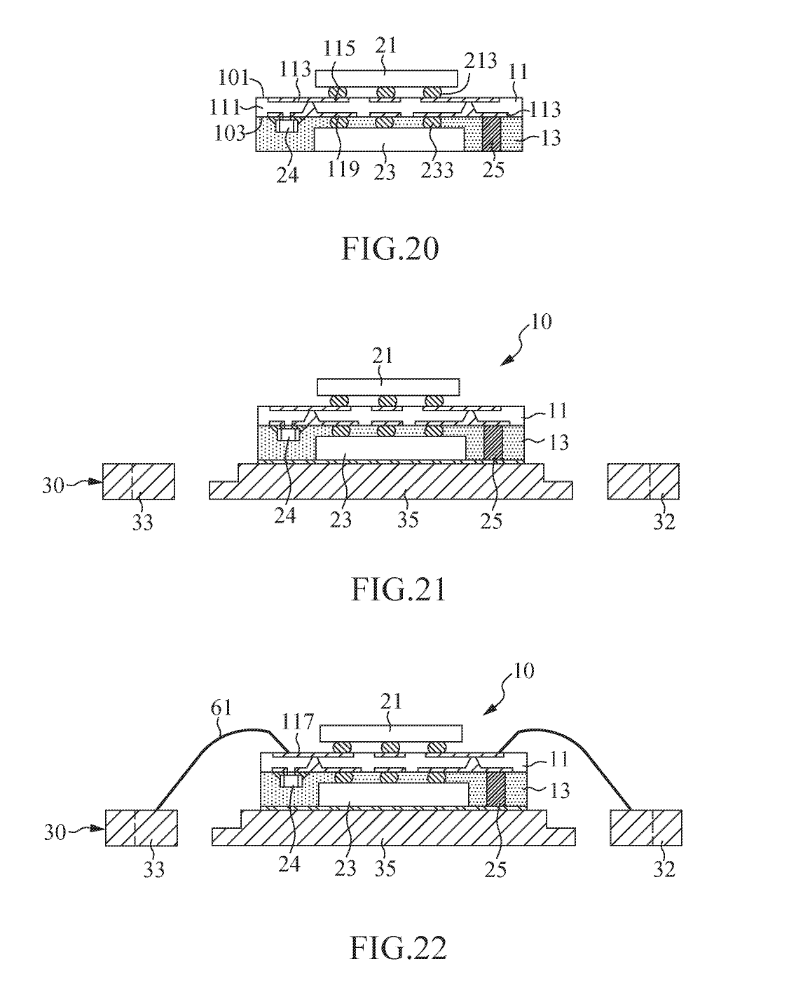

FIGS. 20-24 are schematic views showing a method of making a semiconductor assembly in which the thermal pad has stepped peripheral edges in accordance with the second embodiment of the present invention.

For purposes of brevity, any description in Embodiment 1 is incorporated herein insofar as the same is applicable, and the same description need not be repeated.

FIG. 20 is a cross-sectional view of a stacked semiconductor subassembly 10 having a primary routing circuitry 11, a stiffener 13, a first device 21, a second device 23, a passive component 24 and a metal pillar 25. In this illustration, the primary routing circuitry 11 is a multi-layered buildup circuitry and includes a dielectric layer 111 and a plurality of wiring layers 113 serially formed in an alternate fashion. The first device 21 is electrically coupled to the primary routing circuitry 11 from the first surface 101 of the primary routing circuitry 11, and the second device 23, the passive component 24 and the metal pillar 25 are electrically coupled to the primary routing circuitry 11 from the second surface 103 of the primary routing circuitry 11. In this embodiment, the first device 21 is electrically coupled to first conductive pads 115 of the primary routing circuitry 11 through first conductive bumps 213, whereas the second device 23 is electrically coupled to second conductive pads 119 of the primary routing circuitry 11 through second conductive bumps 233. The stiffener 13 covers the second surface 103 of the primary routing circuitry 11 and surrounds and conformally coats and encapsulates the second device 23, the passive component 24 and the metal pillar 25. As an alternative, the stiffener 13 may be omitted.

FIG. 21 is a cross-sectional view of the structure with the stacked semiconductor subassembly 10 of FIG. 20 attached on an interconnect substrate 30. The interconnect substrate 30 is similar to that illustrated in FIGS. 7 and 8, except that the thermal pad 35 has stepped peripheral edges. In this illustration, the second device 23 is thermally conductible to the thermal pad 35 for heat dissipation, and the metal pillar 25 is electrically connected to the thermal pad 35 for ground connection.

FIG. 22 is a cross-sectional view of the structure with the stacked semiconductor subassembly 10 electrically connected to the interconnect substrate 30 by bonding wires 61. The bonding wires 61 are attached to terminal pads 117 of the primary routing circuitry 11 and the metal leads 33 of the interconnect substrate 30 to electrically connect the stacked semiconductor subassembly 10 to the interconnect substrate 30.

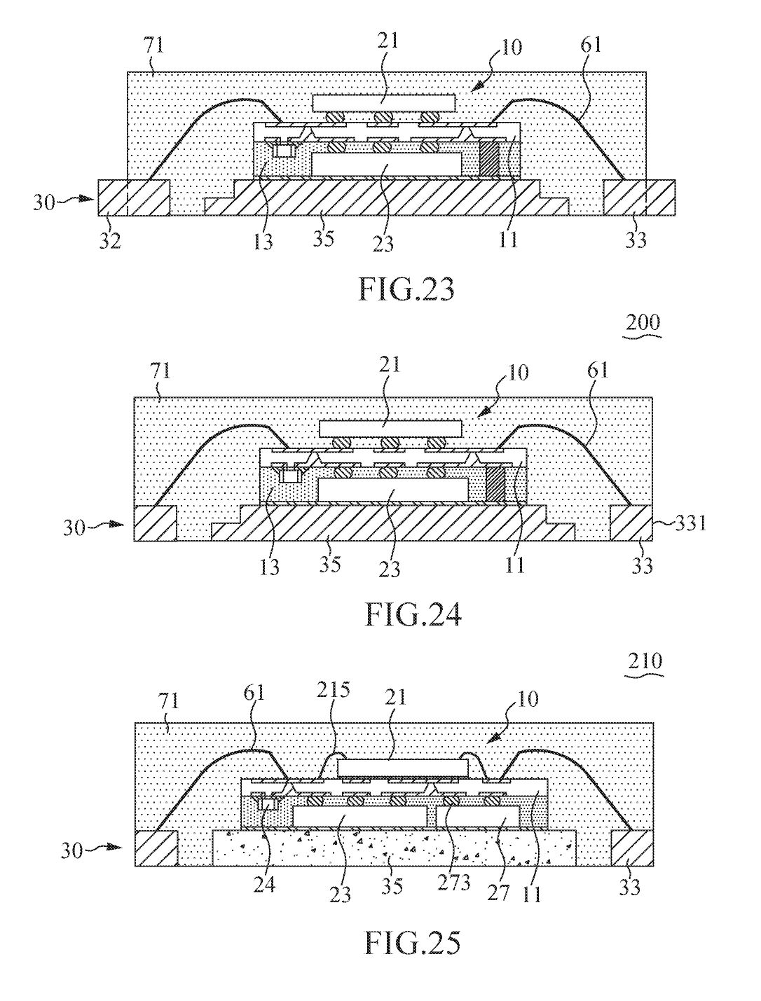

FIG. 23 is a cross-sectional view of the structure provided with a molding compound 71. The molding compound 71 covers and encapsulates the primary routing circuitry 11, the stiffener 13, the first device 21 and the bonding wires 61 from above, and further extends into spaces between the metal leads 33 and gaps between the thermal pad 35 and the metal leads 33. As the molding compound 71 surrounds and conformally coats the thermal pad 35 in lateral directions, the molding compound 71 has a stepped cross-sectional profile where it contacts the stepped peripheral edges of the thermal pad 35. As a result, the molding compound 71 securely interlocks with the interconnect substrate 30 so as to prevent the interconnect substrate 30 from being vertically forced apart from the molding compound 71 and also to avoid micro-cracking at the interface along the vertical direction.

FIG. 24 is a cross-sectional view of a semiconductor assembly 200 separated from the metal frame 32. By chemical etching, mechanical trimming/cutting or sawing, the metal frame 32 is separated from the metal leads 33 to break the connection between the metal leads 33, and the outer ends 331 of the metal leads 33 have a lateral surface flush with peripheral edges of the molding compound 71.

FIG. 25 is a cross-sectional view of another aspect of the semiconductor assembly according to the second embodiment of the present invention. The semiconductor assembly 210 is similar to that illustrated in FIG. 24, except that (i) the first device 21 is electrically connected to the primary routing circuitry 11 by bonding wires 215, (ii) a third device 27 is further provided and electrically coupled to the primary routing circuitry 11 through third conductive bumps 273, and (iii) the thermal pad 35 is a thermally conductive and electrically insulating pad and the interconnect substrate 30 includes no tie bars integral with the thermal pad 35.

### Embodiment 3

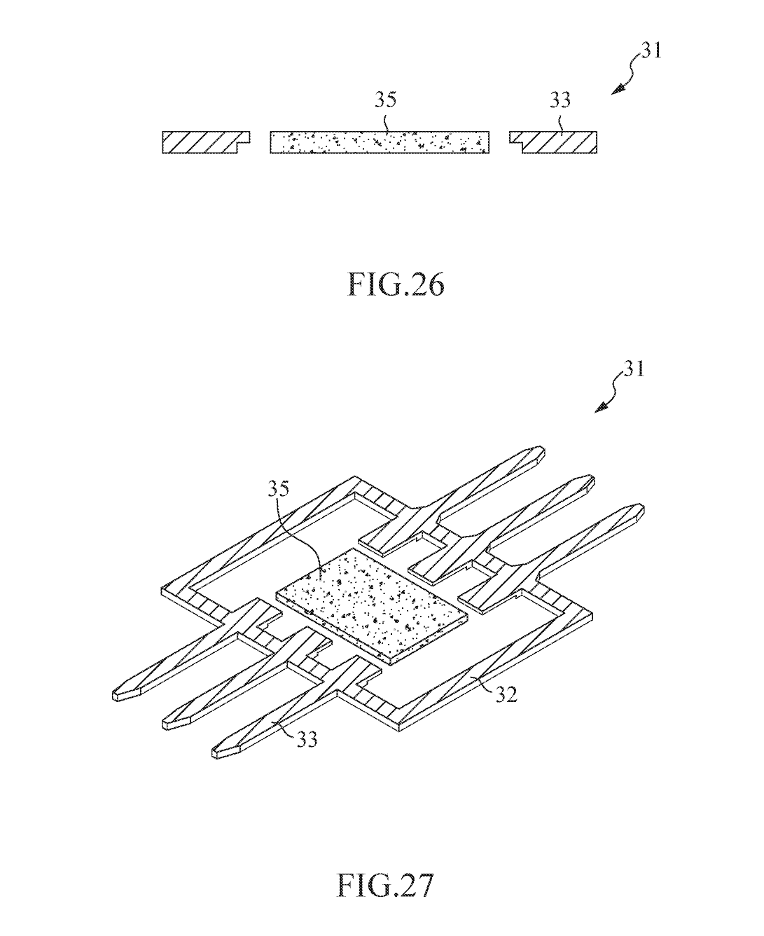

FIGS. 26-33 are schematic views showing a method of making a semiconductor assembly in which the metal leads have stepped peripheral edges in accordance with the third embodiment of the present invention.

For purposes of brevity, any description in the Embodiments above is incorporated herein insofar as the same is applicable, and the same description need not be repeated.

FIGS. 26 and 27 are cross-sectional and top perspective views, respectively, of a lead frame 31 having a metal frame 32, a plurality of metal leads 33 and a thermal pad 35. In this embodiment, the metal leads 33 are shaped into elongated strips parallel to each other and integrally connected to the metal frame 32 and have stepped peripheral edges. The thermal pad 35 is a thermally conductive and electrically insulating pad and located at the central area within the metal frame 32.

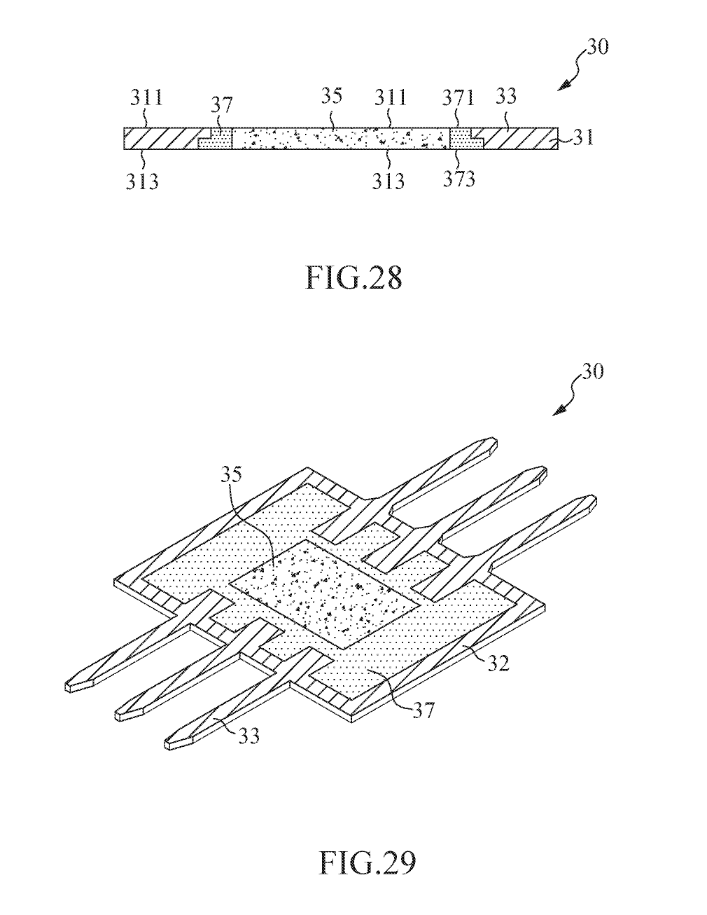

FIGS. 28 and 29 are cross-sectional and top perspective views, respectively, of the structure provided with a compound layer 37. The compound layer 37 can be deposited by applying a molding material into the remaining spaces within the metal frame 32. As a result, the compound layer 37 fills in spaces of the metal leads 33 and gaps between the metal leads 33 and the thermal pad 35 to provide secure bonds between the metal leads 33 and the thermal pad 35. By planarization, the compound layer 37 has a front surface 371 substantially coplanar with front sides 311 of the metal leads 33 and the thermal pad 35, and a back surface 373 substantially coplanar with a back sides 313 of the metal leads 33 and the thermal pad 35. Preferably, the compound layer 37 has an elastic modulus larger than 1.0 GPa and a linear coefficient of thermal expansion in a range from about 5×10⁻⁶ K⁻¹ to about 15×10⁻⁶ K⁻¹. Additionally, as the compound layer 37 surrounds and conformally coats the metal leads 33 in lateral directions, the compound layer 37 has a stepped cross-sectional profile where it contacts the stepped peripheral edges of the metal leads 33. As a result, the compound layer 37 securely interlocks with the lead frame 31 so as to prevent the lead frame 31 from being vertically forced apart from the compound layer 37 and also to avoid micro-cracking at the interface along the vertical direction.

At this stage, an untrimmed interconnect substrate 30 is accomplished and includes the lead frame 31 and the compound layer 37.

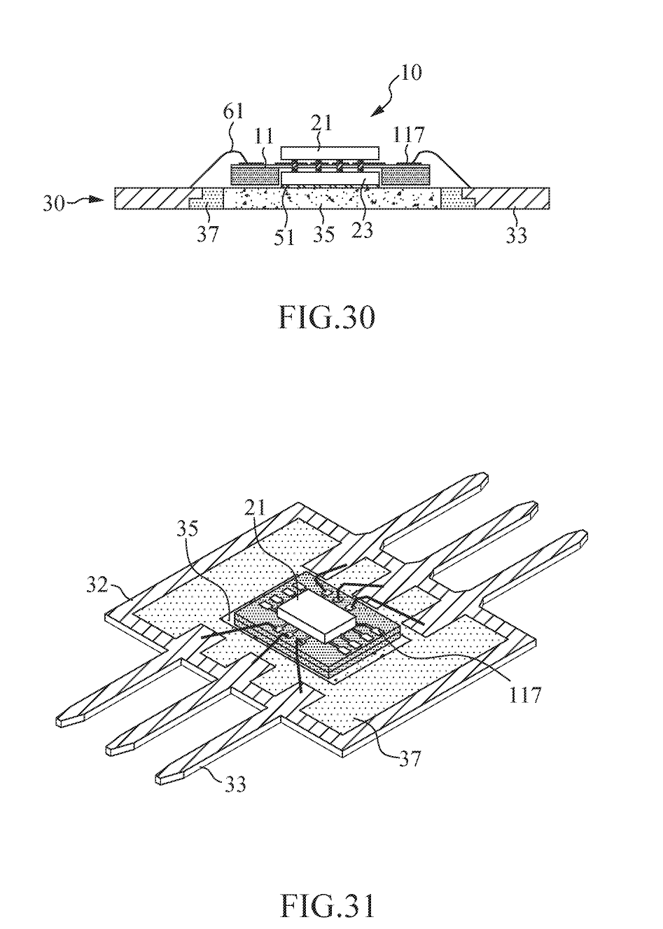

FIGS. 30 and 31 are cross-sectional and top perspective views, respectively, of the structure with the stacked semiconductor subassembly 10 of FIG. 4 electrically connected to the interconnect substrate 30 of FIGS. 28 and 29. The stacked semiconductor subassembly 10 of FIG. 4 is mounted on the thermal pad 35 of the interconnect substrate 30 by a thermal conducting material 51 in contact with the second device 23 and the thermal pad 35, and is electrically connected to the metal leads 33 by bonding wires 61 attached to the terminal pads 117 of the primary routing circuitry 11 and the metal leads 33 of the interconnect substrate 30.

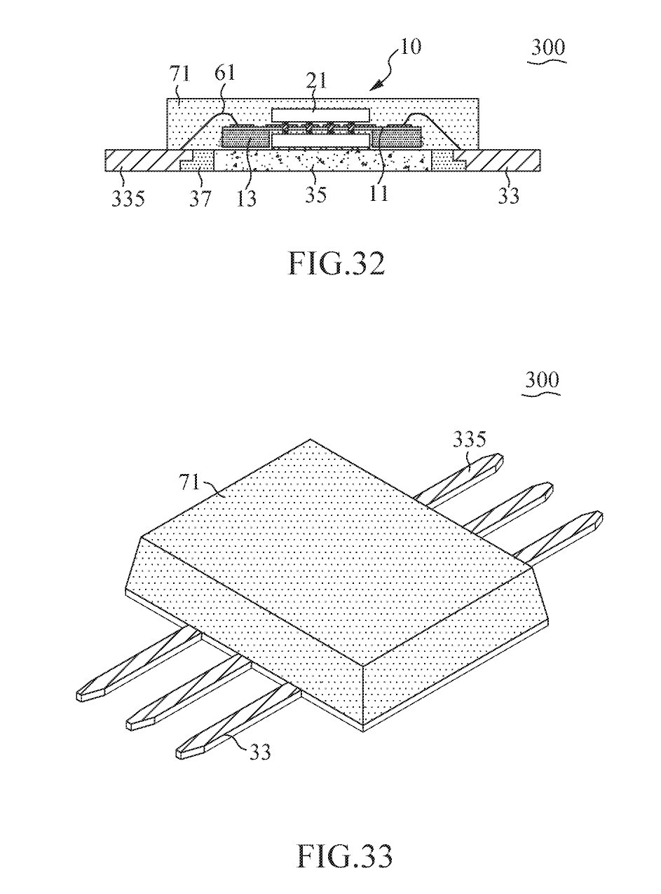

FIGS. 32 and 33 are cross-sectional and top perspective views, respectively, of a semiconductor assembly 300 separated from the metal frame 32 and optionally provided with a molding compound 71. By chemical etching, mechanical trimming/cutting or sawing, the metal frame 32 is separated from the metal leads to break the connection between the metal leads 33. Additionally, the molding compound 71 is optionally provided to cover and encapsulate the primary routing circuitry 11, the stiffener 13, the first device 21 and the bonding wires 61 from above. In this embodiment, each of the metal leads 33 has a horizontally elongated portion 335 laterally extending out of the peripheral edges of the molding compound 71 to form pin terminals for external connection.

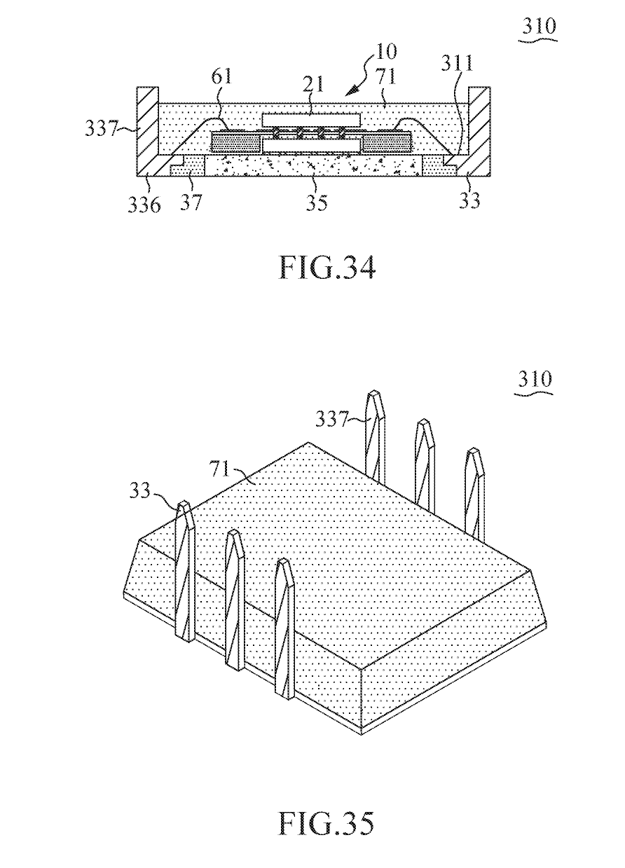

FIGS. 34 and 35 are cross-sectional and top perspective views, respectively, of another aspect of the semiconductor assembly according to the third embodiment of the present invention. The semiconductor assembly 310 is similar to that illustrated in FIGS. 32 and 33, except that the metal leads 33 are bent upwardly and each have a horizontal flat portion 336 and a vertically elongated portion 337. The vertically elongated portion 337 extends from the front side 311 of the horizontal flat portion 336 beyond the exterior surface of the molding compound 71 in the upward direction.

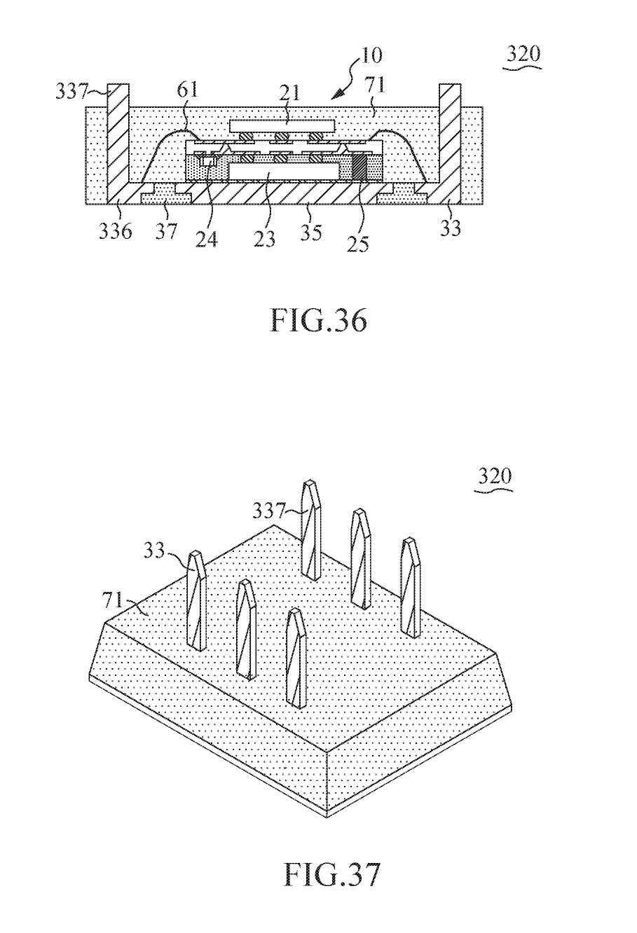

FIGS. 36 and 37 are cross-sectional and top perspective views, respectively, of yet another aspect of the semiconductor assembly according to the third embodiment of the present invention. The semiconductor assembly 320 is similar to that illustrated in FIGS. 34 and 35, except that (i) the stacked semiconductor subassembly 10 of FIG. 20 is used in this aspect, (ii) the vertically elongated portions 337 of the metal leads 33 are surrounded by the molding compound 71 in the lateral directions, and (iii) the thermal pad 35 is a metal pad having stepped peripheral edges. As a result, the compound layer 37 securely interlocks with the metal leads 33 and the thermal pad 35 so as to prevent the metal leads 33 and the thermal pad 35 from being vertically forced apart from the compound layer 37 and also to avoid micro-cracking at the interface along the vertical direction.

### Embodiment 4

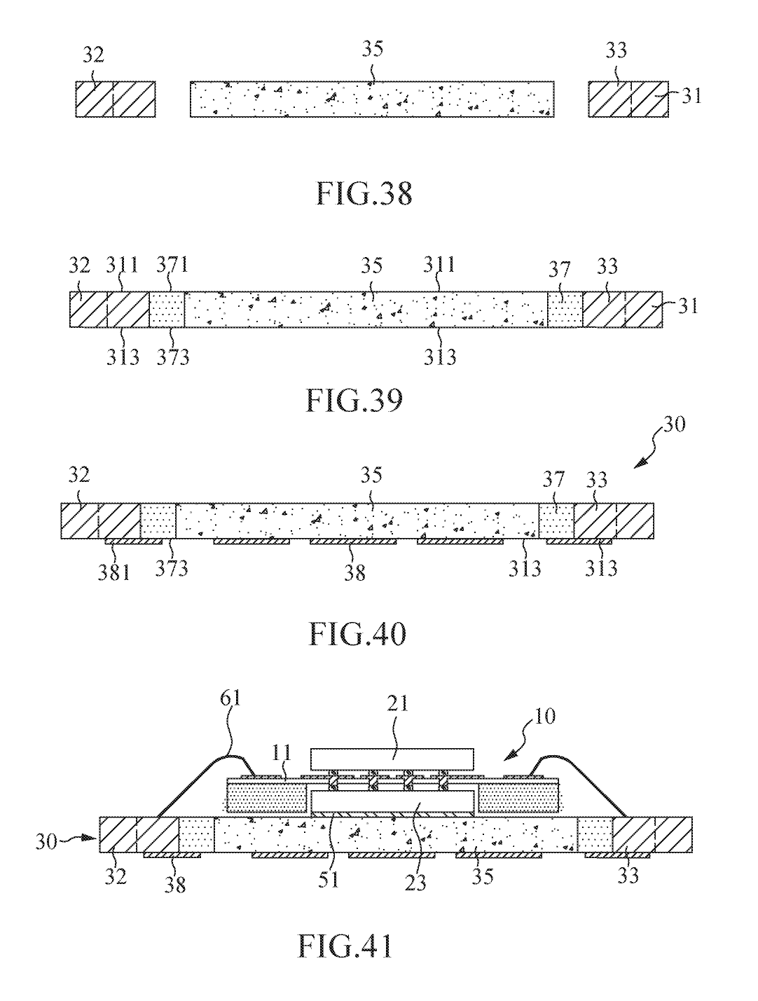

FIGS. 38-42 are schematic views showing a method of making a semiconductor assembly in which the interconnect substrate further includes an external routing circuitry in accordance with the fourth embodiment of the present invention.

For purposes of brevity, any description in the Embodiments above is incorporated herein insofar as the same is applicable, and the same description need not be repeated.

FIG. 38 is a cross-sectional view of a lead frame 31. The lead frame 31 is similar to that illustrated in FIG. 7, except that the thermal pad 35 is a thermally conductive and electrically insulating pad and the lead frame 31 includes no tie bars integral with the thermal pad 35.

FIG. 39 is a cross-sectional view of the structure provided with a compound layer 37. The compound layer 37 fills in spaces of the metal leads 33 and gaps between the metal leads 33 and the thermal pad 35 to provide secure bonds between the metal leads 33 and the thermal pad 35. By planarization, the compound layer 37 has a front surface 371 substantially coplanar with front sides 311 of the metal leads 33 and the thermal pad 35, and a back surface 373 substantially coplanar with a back sides 313 of the metal leads 33 and the thermal pad 35.

FIG. 40 is a cross-sectional view of the structure provided with an external routing circuitry 38 on the back surface 373 of the compound layer 37 and the back sides 313 of the thermal pad 35 and the metal leads 33 and electrically coupled to the metal leads 33. In this illustration, the external routing circuitry 38 is a re-distribution layer 381 and formed by metal pattern deposition described below. The bottom surface of the structure can be metallized to form an electrically conductive layer (typically a copper layer) as a single layer or multiple layers by numerous techniques, such as electroplating, electroless plating, evaporating, sputtering or their combinations. The electrically conductive layer can be made of Cu, Ni, Ti, Au, Ag, Al, their combinations, or other suitable electrically conductive material. Typically, a seeding layer is formed on the bottommost surface of the structure before the electrically conductive layer is electroplated to a desirable thickness. The seeding layer may consist of a diffusion barrier layer and a plating bus layer. The diffusion barrier layer is to counterbalance oxidation or corrosion of the electrically conductive layer such as copper. In most cases, the diffusion barrier layer also acts as an adhesion promotion layer to the underlying material and is formed by physical vapor deposition (PVD) such as sputtered Ti or TiW with a thickness in a range from about 0.01 μm to about 0.1 μm. However, the diffusion barrier layer may be made of other materials, such as TaN, or other applicable materials and its thickness range is not limited to the range described above. The plating bus layer is typically made of the same material as the electrically conductive layer with a thickness in a range from about 0.1 μm to about 1 μm. For example, if the electrically conductive layer is copper, the plating bus layer would preferably be a thin film copper formed by physical vapor deposition or electroless plating. However, the plating bus layer may be made of other applicable materials such as silver, gold, chromium, nickel, tungsten, or combinations thereof and its thickness range is not limited to the range described above.

Following the deposition of the seeding layer, a photoresist layer (not shown) is formed over the seeding layer. The photoresist layer may be formed by a wet process, such as a spin-on process, or by a dry process, such as lamination of a dry film. After the photoresist layer is formed, the photoresist layer is patterned to form openings, which are then filled with plated metal such as copper to form the re-distribution layer 381 having a uniform thickness less than the thickness of the metal leads 33. The plated metal layer typically has a thickness in a range from about 10 μm to about 100 μm. After metal plating, the exposed seeding layer is then removed by etching process to form electrically isolated conductive traces as desired.

At this stage, an untrimmed interconnect substrate 30 is accomplished and includes the metal frame 32, the metal leads 33, the thermal pad 35, the compound layer 37 and the external routing circuitry 38.

FIG. 41 is a cross-sectional view of the structure with the stacked semiconductor subassembly 10 of FIG. 4 electrically connected to the interconnect substrate 30 of FIG. 40. The stacked semiconductor subassembly 10 of FIG. 4 is mounted on the thermal pad 35 of the interconnect substrate 30 by a thermal conducting material 51 in contact with the second device 23 and the thermal pad 35, and is electrically connected to the metal leads 33 by bonding wires 61 attached to the primary routing circuitry 11 and the metal leads 33 of the interconnect substrate 30.

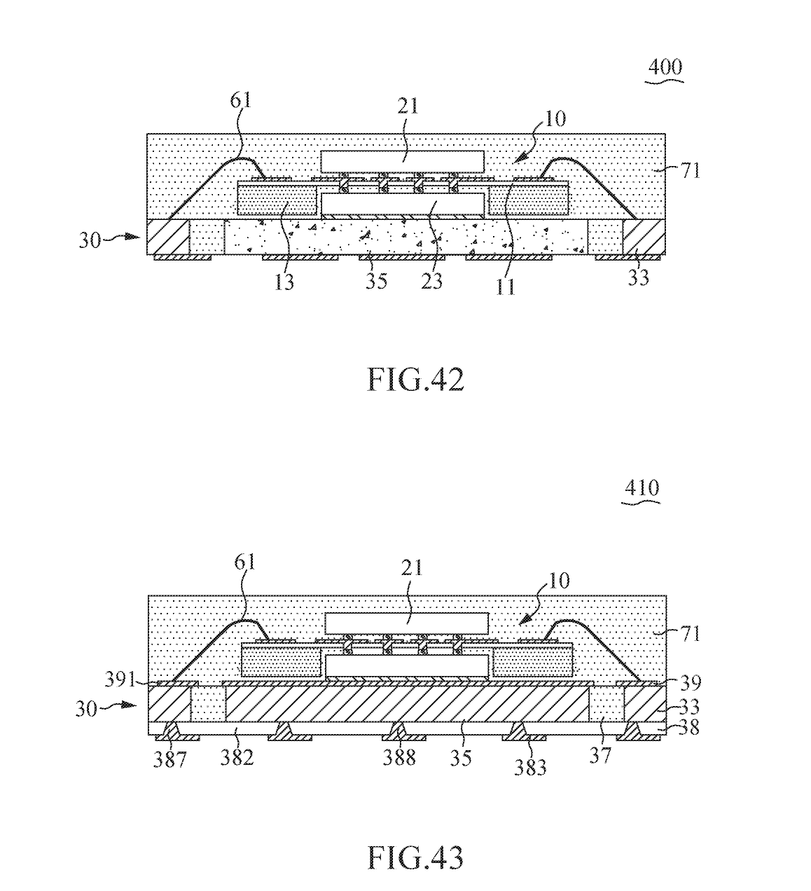

FIG. 42 is a cross-sectional view of a semiconductor assembly 400 separated from the metal frame 32 and optionally provided with a molding compound 71. By chemical etching, mechanical trimming/cutting or sawing, the metal frame 32 is separated from the metal leads 33 to break the connection between the metal leads 33. Additionally, the molding compound 71 is optionally provided to cover and encapsulate the primary routing circuitry 11, the stiffener 13, the first device 21 and the bonding wires 61 from above.

FIG. 43 is a cross-sectional view of another aspect of the semiconductor assembly according to the fourth embodiment of the present invention. The semiconductor assembly 410 is similar to that illustrated in FIG. 42, except that (i) the thermal pad 35 is a metal pad, and the external routing circuitry 38 is a buildup circuitry, (ii) the interconnect substrate 30 further includes another external routing circuitry 39 on the front surface of the compound layer 37 as well as the front sides of the metal leads 33 and the thermal pad 35, and (iii) the bonding wires 61 electrically connect the stacked semiconductor subassembly 10 to the additional external routing circuitry 39. In this illustration, the external routing circuitry 38 at the bottom of the interconnect substrate 30 is a multi-layered buildup circuitry and includes a dielectric layer 382 and a wiring layer 383 serially formed in an alternate fashion, whereas the additional external routing circuitry 39 at the top of the interconnect substrate 30 is a re-distribution layer 391 thinner than the metal leads 33. The dielectric layer 382 covers the metal leads 33, the thermal pad 35 and the compound layer 37 from below. The wiring layer 383 extends laterally on the dielectric layer 382 and has conductive vias 387 in contact with the metal leads 33 for electrical routing and additional conductive vias 388 in contact with the thermal pad 35 for thermal conduction and ground connection. The re-distribution layer 391 laterally extends on the front surface of the compound layer 37 and the front sides of the thermal pad 35 and the metal leads 33 and is electrically coupled to the metal leads 33. As a result, the re-distribution layer 391 can be electrically connected to the wiring layer 383 through the metal leads 33.

### Embodiment 5

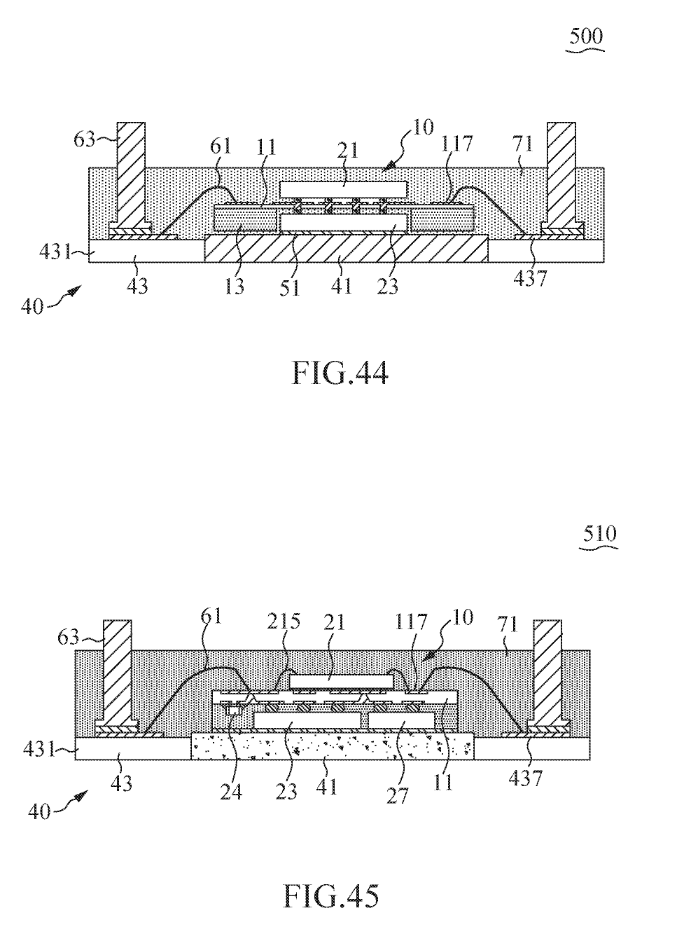

FIG. 44 is a cross-sectional view of a semiconductor assembly in accordance with the fifth embodiment of the present invention.

For purposes of brevity, any description in the Embodiments above is incorporated herein insofar as the same is applicable, and the same description need not be repeated.

The semiconductor assembly 500 includes the stacked semiconductor subassembly 10 of FIG. 4, another interconnect substrate 40 that includes a thermal pad 41 and a surrounding layer 43, a plurality of bonding wires 61, a plurality of terminals 63 and optionally a molding compound 71. The thermal pad 41 is illustrated as a metal slug and has a front side attached to the second device 23 of the stacked semiconductor subassembly 10 of FIG. 4 by a thermal conducting material 51, and is laterally surrounded by the surrounding layer 43. In this embodiment, the surrounding layer 43 is a multi-layered buildup circuitry and includes a dielectric layer 431 and contact pads 437 on the dielectric layer 431. The dielectric layer 431 is bonded to sidewalls of the thermal pad 41, whereas the contact pads 437 are deposited on the front surface of the dielectric layer 431. The bonding wires 61 are attached to the terminal pads 117 of the primary routing circuitry 11 and the contact pads 437 of the surrounding layer 43 to provide electrical connection between the primary routing circuitry 11 and the surrounding layer 43. The terminals 63 are electrically coupled to the contact pads 437 and disposed about peripheral edges of the stacked semiconductor subassembly 10 to provide electrical contacts for next-level connection. The molding compound 71 encapsulates the stacked semiconductor subassembly 10 and the bonding wires 61, and partially covers sidewalls of the terminals 63. As shown in FIG. 44, the terminals 63 extend beyond the exterior surface of the molding compound 71 in the upward direction to form pin terminals for external connection.

FIG. 45 is a cross-sectional view of another aspect of the semiconductor assembly according to the fifth embodiment of the present invention. The semiconductor assembly 510 is similar to that illustrated in FIG. 44, except that the stacked semiconductor subassembly 10 illustrated in FIG. 25 is used in this aspect and the thermal pad 41 is a thermally conductive and electrically insulating slug. The thermally conductive and electrically insulating slug typically is made of a material having high elastic modulus and low coefficient of thermal expansion (for example, 2×10⁻⁶ K⁻¹ to 10×10⁻⁶ K⁻¹), such as ceramic, silicon, glass or others. In this embodiment, the thermal pad 41 is a ceramic slug.

### Embodiment 6

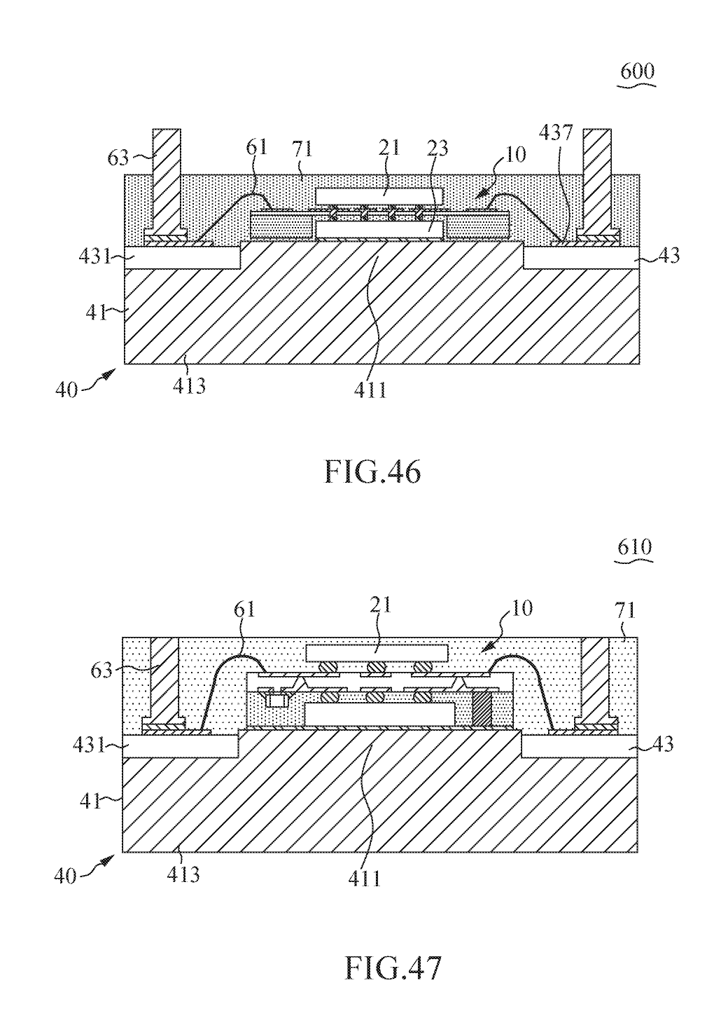

FIG. 46 is a cross-sectional view of a semiconductor assembly in accordance with the sixth embodiment of the present invention.

For purposes of brevity, any description in the Embodiments above is incorporated herein insofar as the same is applicable, and the same description need not be repeated.

The semiconductor assembly 600 is similar to that illustrated in FIG. 42, except that the thermal pad 41 includes a post 411 and a base 413. The post 411 contacts and projects from the base 413 and has sidewalls bonded to the dielectric layer 431 of the surrounding layer 43 and is attached to the second device 23. The base 413 is below the post 411 and extends laterally from the post 411 in lateral directions to be covered by the dielectric layer 431 of the surrounding layer 43 from above. In this embodiment, the post 411 has a thickness in a range of 0.05 to 0.1 mm, whereas the base 413 has a thickness in a range of 0.3 to 3 mm. Preferably, the post 411 and the base 413 are integral with each other. For instance, the thermal pad 41 may be a selectively etched single-piece metal or a stamped single-piece metal. By a wet etching or stamping process, the thermal pad 41 is shaped to include the post 411 and the base 413. Alternatively, the post 411 may be deposited on the base 413 by numerous metal deposition techniques, such as electroplating, chemical vapor deposition, physical vapor deposition or others. In this alternative case, the post 411 and base 413 have a metallurgical interface and are in contact with but not integral with each other.

FIG. 47 is a cross-sectional view of another aspect of the semiconductor assembly according to the sixth embodiment of the present invention. The semiconductor assembly 610 is similar to that illustrated in FIG. 46, except that the stacked semiconductor subassembly 10 of FIG. 20 is used in this aspect and the exterior surfaces of the terminals 63 and the molding compound 71 are flush with each other in the upward direction.

As illustrated in the aforementioned embodiments, a distinctive semiconductor assembly is configured and includes a stacked semiconductor subassembly electrically coupled to an interconnect substrate by a plurality of bonding wires. For improved heat dissipation, the interconnect substrate preferably includes a thermal pad surrounded by metal leads or a surrounding layer, and the stacked semiconductor subassembly is attached to the thermal pad of the interconnect substrate. Optionally, a molding compound may be further provided to encapsulate the stacked semiconductor subassembly and the bonding wires. For the convenience of below description, the direction in which the first surface of the primary routing circuitry faces is defined as the first direction, and the direction in which the second surface of the primary routing circuitry faces is defined as the second direction.

The stacked semiconductor subassembly includes a first device and a second device electrically connected to each other. More specifically, the stacked semiconductor subassembly can further include a primary routing circuitry between the first device and the second device, and optionally includes a stiffener bonded to the primary routing circuitry and laterally surrounding the second device. The primary routing circuitry can be a buildup circuitry without a core layer to provide primary fan-out routing/interconnection and the shortest interconnection distance between the first and second devices. Preferably, the primary routing circuitry is a multi-layered buildup circuitry and includes at least one dielectric layer and at least one wiring layer that extend laterally on the dielectric layer and has conductive vias in the dielectric layer. The dielectric layer and the wiring layer are serially formed in an alternate fashion and can be in repetition when needed. Accordingly, the primary routing circuitry can be formed with first conductive pads and optionally terminal pads at its first surface and second conductive pads at its second surface. The first conductive pads and the terminal pads can be electrically connected to the second conductive pads through conductive vias. In a preferred embodiment, the terminal pads are provided for bonding wire connection and have larger pad size and pad pitch than those of the first conductive pads, the second conductive pads and I/O pads of the first and second devices. The optional stiffener laterally extends to peripheral edges of the primary routing circuitry to provide mechanical support for the primary routing circuitry from the second direction. The stiffener can conformally coat and encapsulate the second device, or have an aperture aligned with the second conductive pads to expose the second conductive pads of the primary routing circuitry from the second direction. Accordingly, the second surface of the primary routing circuitry and an interior sidewall surface of the aperture of the stiffener can form a cavity in the aperture of the stiffener, and the second device can be disposed in the cavity and electrically coupled to the second conductive pads from the second surface of the primary routing circuitry. In a preferred embodiment, the stiffener has a thickness substantially equal to the combined thickness of the second device and the second conductive pads.

The first and second devices each may be a packaged or unpackaged chip or a passive component. The first device can be electrically coupled to the primary routing circuitry by a well-known flip chip bonding process with its active surface facing in the primary routing circuitry using conductive bumps without metallized vias in contact with the first device, or by wire bonding process with its active surface facing away the primary routing circuitry using bonding wires. Likewise, the second device can be electrically coupled to the primary routing circuitry by a well-known flip chip bonding process with its active surface facing in the primary routing circuitry using conductive bumps without metallized vias in contact with the second device. In a preferred embodiment, the second device is disposed within the aperture of the stiffener and has peripheral edges spaced from the interior sidewall surface of the aperture of the stiffener.

The interconnect substrate can include a lead frame and optionally a compound layer bonded with the lead frame. The lead frame mainly includes a thermal pad attached to the second device and a plurality of metal leads electrically connected to the stacked semiconductor subassembly from the first surface of the primary routing circuitry by bonding wires. The metal leads surround sidewalls of the thermal pad and can serve as signal horizontal and vertical transduction pathways or provide ground/power plan for power delivery and return. Preferably, the metal leads have flat front sides substantially coplanar with the flat front side of the thermal pad from the first direction and flat back sides substantially coplanar with the flat back side of the thermal pad from the second direction. The optional compound layer fills in spaces between the metal leads and gaps between the thermal pad and the metal leads, with the thermal pad and the metal leads not covered by the compound layer from the first and second directions. Specifically, the compound layer may have a front surface substantially coplanar with the front sides of the thermal pad and the metal leads from the first direction and a back surface substantially coplanar with the back sides of the thermal pad and the metal leads from the second direction. Alternatively, the spaces between the metal leads and the gaps between the thermal pad and the metal leads may be filled with the optional molding compound that encapsulates the stacked semiconductor subassembly and the bonding wires.

The metal leads laterally extend beyond peripheral edges of the primary routing circuitry, and each have an inner end directed toward the sidewalls of the thermal pad and an outer end situated farther away from the thermal pad than the inner end. Typically, the metal leads have a thickness between the front side and the back side in a range from about 0.15 mm to about 1.0 mm, which are thicker than the wiring layer of the primary routing circuitry. Additionally, the metal leads may laterally extend to the peripheral edges of the molding compound and/or the compound layer, or have a horizontally elongated portion laterally extending beyond the peripheral edges of the molding compound and/or the compound layer. Alternatively, the metal leads may be configured into a bent shape and have a horizontal flat portion and a vertically elongated portion. In a preferred embodiment, the front and back sides of the horizontal flat portion are substantially coplanar with those of the thermal pad, whereas the vertically elongated portion protrudes from the front side of the horizontal flat portion and extends beyond an exterior surface of the molding compound in the first direction. As a result, the vertically elongated portion, surrounding the peripheral edges of the stacked semiconductor subassembly, can provide external electrical contacts for next-level electrical connection. Before trimming the lead frame, the metal leads are integral with a metal frame. Preferably, the metal leads are separated from the metal frame after provision of the compound layer or the molding compound. For secure bonds between the metal leads and the compound layer or between the metal leads and the molding compound, the metal leads may have a stepped peripheral edges interlocked with the compound layer or the molding compound. As a result, the compound layer or the molding compound also has a stepped cross-sectional profile where it contacts the metal leads so as to prevent the metal leads from being vertically forced apart from the compound layer or the molding compound and also to avoid micro-cracking at the interface along the first and second directions.

The thermal pad can be a metal pad or a thermally conductive and electrically insulating pad, and serves as a primary heat conduction platform for the second device attached thereon, so that the heat generated by the second device can be conducted away. Before the trimming process, the metal pad can be connected to the metal frame by tie bars. Additionally, the thermally conductive and electrically insulating pad may be made of ceramic, silicon, glass or others and typically has high elastic modulus and low coefficient of thermal expansion (for example, 2×10⁻⁶ K⁻¹ to 10×10⁻⁶ K⁻¹). As a result, the thermally conductive and electrically insulating pad, having CTE matching a semiconductor device to be assembled thereon, provides a CTE-compensated platform for the second device, and thus internal stresses caused by CTE mismatch can be largely compensated or reduced. Likewise, the thermal pad may have stepped peripheral edges, and the compound layer or the molding compound has a stepped cross-sectional profile where it contacts the thermal pad so as to prevent the thermal pad from being vertically forced apart from the compound layer or the molding compound and also to avoid micro-cracking at the interface along the first and second directions.

Optionally, the interconnect substrate may further include an external routing circuitry disposed on the back surface of the compound layer and electrically coupled to the metal leads. As a result, electrical signal can be re-distributed from the peripheral leads to the designated location. The external routing circuitry may be a re-distribution layer formed by metal deposition using photolithographic process and having a uniform thickness less than the thickness of the metal leads. In a preferred embodiment, the re-distribution layer contacts and laterally extends on the back surface of the compound layer and further laterally extends onto the back sides of the metal leads and optionally the back side of the thermal pad. Alternatively, the external routing circuitry may be a multi-layered buildup circuitry that covers the back surface of the compound layer and the back sides of the metal leads and the thermal pad. The buildup circuitry can include at least one dielectric layer and at least one wiring layer that extends through the dielectric layer to form conductive vias and extends laterally on the dielectric layer. As a result, the wiring layer can be electrically coupled to the metal leads through conductive vias in contact with the metal leads and optionally be thermally conductible to and/or grounded to the thermal pad through conductive vias in contact with the thermal pad. The dielectric layer and the wiring layer are serially formed in an alternate fashion and can be in repetition when needed.

Optionally, the interconnect substrate may further include an additional external routing circuitry disposed on the front surface of the compound layer and electrically coupled to the metal leads. By double external routing circuitries on two sides of the compound layer, the routing flexibility of the interconnect substrate can be enhanced. The additional external routing circuitry may be a re-distribution layer formed by metal deposition using photolithographic process and having a uniform thickness less than the thickness of the metal leads. In a preferred embodiment, the additional re-distribution layer contacts and laterally extends on the front surface of the compound layer and further laterally extends onto the front sides of the metal leads and optionally the front side of the thermal pad. As a result, the double external routing circuitries can be electrically connected to each other through the metal leads.

The combination of the thermal pad and the surrounding layer also can be used as the interconnect substrate to provide a primary heat conduction platform for the second device and electrical contacts for connection with the primary routing circuitry. The thermal pad may be a metal slug or a thermally conductive and electrically insulating slug, and has sidewalls laterally surrounded by the surrounding layer. In a preferred embodiment, the thermal pad includes a post and a base, and the second device is attached on the post of the thermal pad. The post and the base can be integrated as one piece and may be made of the same metal. The post contacts and projects from the base and has sidewalls bonded to the surrounding layer, whereas the base extends laterally from the post to peripheral edges of the surrounding layer and is covered by the surrounding layer in the first direction. Accordingly, the post can provide a platform for device attachment, whereas the base offers a larger thermal dissipation surface area than the post and mechanical support for the assembly to prevent warpage.

The surrounding layer of the interconnect substrate can be a buildup circuitry without a core layer to provide electrical contacts for connection with the primary routing circuitry by bonding wires. Preferably, the surrounding layer is a multi-layered buildup circuitry and includes at least one dielectric layer and at least one wiring layer that extend laterally on the dielectric layer. The dielectric layer and the wiring layer are serially formed in an alternate fashion and can be in repetition when needed. Accordingly, the surrounding layer can be formed with contact pads electrically connected to the primary routing circuitry by bonding wires. For next-level connection, a plurality of terminals are further provided in electrical connection with the contact pads of the surrounding layer. In a preferred embodiment, the terminals have a thickness larger than the combined thickness of the primary routing circuitry, the first device and the second device, and extend beyond the exterior surface of the molding compound in the first direction. Alternatively, the terminals can have an exterior surface flush with that of the molding compound. As a result, the terminals can provide electrical contacts for external connection from the first direction.

The bonding wires provide electrical connections between the primary routing circuitry and the interconnect substrate. Specifically, the bonding wires can electrically connect the primary routing circuitry to the metal leads or the contact pads of the surrounding layer from the first surface of the primary routing circuitry and the front sides of the metal leads/the surrounding layer. For instance, when the stacked semiconductor subassembly is assembled on the interconnect substrate having metal leads, the bonding wires can be attached to the first surface of the primary routing circuitry and the front sides of the metal leads. Alternatively, the bonding wires can be attached to the first surface of the primary routing circuitry and the additional external routing circuitry on the front sides of the metal leads. Likewise, when the stacked semiconductor subassembly is assembled to the interconnect substrate having surrounding layer bonded with the thermal pad, the bonding wires can be attached to the first surface of the primary routing circuitry and the contact pads at the front side of the surrounding layer. By the bonding wires, the first device and second device can be electrically connected to the metal leads or the surrounding layer of the interconnect substrate for next-level connection.

The term “cover” refers to incomplete or complete coverage in a vertical and/or lateral direction. For instance, in a preferred embodiment, the base of the thermal pad covers the surrounding layer from the second direction regardless of whether another element is between the base and the surrounding layer.

The phrases “attached to” and “mounted on” includes contact and non-contact with a single or multiple support element(s). For instance, in a preferred embodiment, the second device can be attached to the thermal pad regardless of whether the second device is separated from the thermal pad by the thermal conducting material.

The phrases “electrical connection”, “electrically connected” and “electrically coupled” refer to direct and indirect electrical connection. For instance, in a preferred embodiment, the first and second devices can be electrically connected to the terminals by the primary routing circuitry, the surrounding layer and the bonding wires but does not contact the terminals.

The “first direction” and “second direction” do not depend on the orientation of the semiconductor assembly, as will be readily apparent to those skilled in the art. For instance, the first surface of the primary routing circuitry faces the first direction and the second surface of the primary routing circuitry faces the second direction regardless of whether the semiconductor assembly is inverted. Thus, the first and second directions are opposite one another and orthogonal to the lateral directions.

The semiconductor assembly according to the present invention has numerous advantages. The primary routing circuitry provides a first level fan-out routing/interconnection and the shortest interconnect distance between the first and second devices. The stiffener can provide mechanical support for the primary routing circuitry. The thermal pad establishes a heat dissipation pathway for spreading out the heat generated by the second device. The metal leads or the combination of the surrounding layer and the terminals provide further routing to increase routing flexibility of the assembly. As the primary routing circuitry is connected to the metal leads or the surrounding layer by bonding wires, not by direct build-up process, the simplified process steps result in lower manufacturing cost. The semiconductor assembly made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A three-dimensional semiconductor assembly, comprising:
a stacked semiconductor subassembly that includes a primary routing circuitry, a first device and a second device, wherein (i) the primary routing circuitry has a first surface in a first direction, a second surface in an opposite second direction, first conductive pads at the first surface, and second conductive pads at the second surface electrically connected to the first conductive pads, (ii) the first device is disposed over the first surface of the primary routing circuitry and electrically coupled to the primary routing circuitry through the first conductive pads, and (iii) the second device is disposed over the second surface of the primary routing circuitry and electrically coupled to the primary routing circuitry through the second conductive pads;
an interconnect substrate having a thermal pad and a plurality of metal leads disposed about a periphery of the thermal pad, wherein the thermal pad and the metal leads each have a front side facing in the first direction and the front side of the thermal pad is attached to the second device by a thermal conducting material; and
a plurality of bonding wires that electrically connect the first surface of the primary routing circuitry to the front sides of the metal leads.

2. The semiconductor assembly of claim 1, wherein the stacked semiconductor subassembly further includes a stiffener that is bonded to the primary routing circuitry and laterally surrounds the second device.

3. The semiconductor assembly of claim 2, wherein (i) the stiffener has an aperture, (ii) a portion of the second surface of the primary routing circuitry and an interior sidewall surface of the aperture of the stiffener form a cavity in the aperture of the stiffener, and (iii) the second device is disposed in the cavity.

4. The semiconductor assembly of claim 1, further comprising a molding compound that encapsulates the first device, the bonding wires and the primary routing circuitry.

5. The semiconductor assembly of claim 4, wherein the molding compound further extends into spaces between the metal leads and gaps between the thermal pad and the metal leads.

6. The semiconductor assembly of claim 4, wherein each of the metal leads has a horizontally elongated portion extending beyond peripheral edges of the molding compound.

7. The semiconductor assembly of claim 1, wherein the interconnect substrate further has a compound layer that fills in spaces between the metal leads and gaps between the thermal pad and the metal leads and has a front surface substantially coplanar with the front sides of the thermal pad and the metal leads.

8. The semiconductor assembly of claim 1, wherein each of the metal leads has a vertically elongated portion extending from the front side thereof in the first direction.

9. The semiconductor assembly of claim 8, further comprising a molding compound that encapsulates the first device, the bonding wires and the primary routing circuitry and has an exterior surface facing in the first direction, wherein the vertically elongated portions of the metal leads extend beyond the exterior surface of the molding compound in the first direction.

10. The semiconductor assembly of claim 1, wherein the thermal pad is a thermally conductive and electrically insulating pad or a metal pad.

11. The semiconductor assembly of claim 5, wherein at least one of the thermal pad and the metal leads has stepped peripheral edges interlocked with the molding compound.

12. The semiconductor assembly of claim 7, wherein at least one of the thermal pad and the metal leads has stepped peripheral edges interlocked with the compound layer.

13. The semiconductor assembly of claim 1, wherein the first device is electrically connected to the first conductive pads by first conductive bumps or additional bonding wires, and the second device is electrically connected to the second conductive pads by second conductive bumps.

14. The semiconductor assembly of claim 7, wherein the interconnect substrate further has an external routing circuitry disposed on a back surface of the compound layer and electrically coupled to the metal leads.

15. The semiconductor assembly of claim 14, wherein the interconnect substrate further has an additional external routing circuitry disposed on the front surface of the compound layer and electrically coupled to the metal leads, and the bonding wires are electrically connected to the metal leads through the additional external routing circuitry.

16. A three-dimensional semiconductor assembly, comprising:
a stacked semiconductor subassembly that includes a primary routing circuitry, a first device and a second device, wherein (i) the primary routing circuitry has a first surface in a first direction, a second surface in an opposite second direction, first conductive pads at the first surface, and second conductive pads at the second surface electrically connected to the first conductive pads, (ii) the first device is disposed over the first surface of the primary routing circuitry and electrically coupled to the primary routing circuitry through the first conductive pads, and (iii) the second device is disposed over the second surface of the primary routing circuitry and electrically coupled to the primary routing circuitry through the second conductive pads;
an interconnect substrate that includes a thermal pad and a surrounding layer, wherein (i) the thermal pad has a front side facing in the first direction and the front side of the thermal pad is attached to the second device by a thermal conducting material, (ii) the surrounding layer has a dielectric layer and contact pads, (iii) the dielectric layer is bonded to sidewalls of the thermal pad and has a front surface facing in the first direction, and (iv) the contact pads are disposed on the front surface of the dielectric layer;
a plurality of terminals that are electrically coupled to the contact pads and disposed about peripheral edges of the stacked semiconductor subassembly; and
a plurality of bonding wires that are attached to the primary routing circuitry and the contact pads of the surrounding layer to electrically connect the stacked semiconductor subassembly to the terminals.

17. The semiconductor assembly of claim 16, wherein the stacked semiconductor subassembly further includes a stiffener that is bonded to the primary routing circuitry and laterally surrounds the second device.

18. The semiconductor assembly of claim 16, further comprising a molding compound that encapsulates the first device, the bonding wires and the primary routing circuitry and at least partially covers sidewalls of the terminals.

19. The semiconductor assembly of claim 18, wherein the terminals extend beyond an exterior surface of the molding compound in the first direction.

20. The semiconductor assembly of claim 16, wherein the thermal pad is a metal slug or a thermally conductive and electrically insulating slug.

21. The semiconductor assembly of claim 16, wherein the thermal pad includes a post and a base, wherein the post contacts and projects from the base and has sidewalls bonded to the dielectric layer of the surrounding layer, and the base extends laterally from the post in lateral directions and is covered by the dielectric layer of the surrounding layer in the first direction.

22. The semiconductor assembly of claim 16, wherein the first device is electrically connected to the first conductive pads by first conductive bumps or additional bonding wires, and the second device is electrically connected to the second conductive pads by second conductive bumps.
